(19) United States
(12) Patent Application Publication
(10) Pub. No.: US 2026/0131363 A1
(43) Pub. Date: May 14, 2026

(54) WAFER STORAGE CONTAINER CLEANING DEVICE AND WAFER STORAGE CONTAINER CLEANING METHOD

(71) Applicants: SHIBAURA MECHATRONICS CORPORATION, Yokohama-shi (JP); Kioxia Corporation, Tokyo (JP)

(72) Inventors: Yukinobu NISHIBE, Kanagawa (JP); Hisaaki MIYASAKO, Kanagawa (JP); Junji ISHIHARA, Kanagawa (JP); Tooru MIKAMI, Yokkaichi (JP); Naoki KANDA, Yokkaichi (JP); Hiroshi TOMITA, Muko (JP); Jin OTONARI, Yokkaichi (JP)

(73) Assignees: SHIBAURA MECHATRONICS CORPORATION, Yokohama-shi (JP); Kioxia Corporation, Tokyo (JP)

(21) Appl. No.: 19/388,456

(22) Filed: Nov. 13, 2025

(30) Foreign Application Priority Data
Nov. 13, 2024 (JP) 2024-198024

(51) Int. Cl. B08B 9/46; B08B 9/08; B25J 11/00; H01L 21/673

(52) U.S. Cl. CPC B08B 9/46; B08B 9/0826; B25J 11/0085; B08B 2209/08; H10P 72/19

(57) ABSTRACT

A wafer storage container cleaning device according to an embodiment includes a first inspection unit that inspects a grip target portion of a wafer storage container; a cleaning unit that cleans a storage space storing the wafer, in the container; a second inspection unit that inspects the storage space; a robot that conveys the container from the first inspection unit to the cleaning unit and conveys the container from the cleaning unit to the second inspection unit; and a control unit that controls the robot. The control unit controls the robot to convey the container from the first inspection unit to the cleaning unit when the container is determined to be in a usable state, and controls the robot to convey the container from the first inspection unit to a position different from that of the cleaning unit when the container is determined not to be in the usable state.

### CROSS-REFERENCE TO RELATED APPLICATIONS

The present application claims priority to and incorporates by reference the entire contents of Japanese Patent Application No. 2024-198024 filed in Japan on Nov. 13, 2024.

### BACKGROUND OF THE INVENTION

### 1. Field of the Invention

Embodiments of the present invention relate to a wafer storage container cleaning device and a wafer storage container cleaning method.

### 2. Description of the Related Art

Conventionally, there is a wafer storage container cleaning device that cleans and dries wafer storage containers such as a front opening unified pod (FOUP) and a front opening shipping box (FOSB) that store (house) semiconductor wafers.

In the wafer storage container cleaning device, the wafer storage container is conveyed into the device, and a robot conveys the wafer storage container to a cleaning chamber in a state of gripping the wafer storage container. Then, the cleaning chamber performs cleaning processing on the wafer storage container. Then, after the cleaning processing, the dried wafer storage container is unloaded to the outside of the wafer storage container cleaning device.

In addition, there is an inspection device that inspects the inside of the wafer storage container.

Here, in the wafer storage container cleaning device, there is a demand from a user to efficiently clean the wafer storage container while inspecting the wafer storage container.

### BRIEF DESCRIPTION OF THE DRAWINGS

FIG. 1 is a plan view illustrating an example of a schematic configuration of a wafer storage container cleaning device according to an embodiment;

FIG. 2 is a side view illustrating an example of a load port and a first inspection unit according to the embodiment;

FIG. 3 is a diagram illustrating an example of a configuration of the first inspection unit according to the embodiment;

FIG. 4 is a diagram illustrating an example of a configuration of a second inspection unit according to the embodiment;

FIG. 5 is a diagram illustrating an example of a configuration of a control unit according to the embodiment; and

FIG. 6 is a flowchart illustrating a flow of an example of processing executed by the wafer storage container cleaning device according to the embodiment.

### DETAILED DESCRIPTION OF THE PREFERRED EMBODIMENTS

An embodiment of the present invention has been made to solve the above problems, and an object thereof is to provide a wafer storage container cleaning device and a wafer storage container cleaning method capable of performing inspection on a wafer storage container and efficiently cleaning the wafer storage container.

In order to solve the above-described problems and achieve the object, a wafer storage container cleaning device according to an aspect of the present embodiment includes: a first inspection unit that inspects a state of a grip target portion of a wafer storage container; a cleaning unit that cleans at least a storage space in which a wafer is stored, in the wafer storage container; a second inspection unit that inspects a state of the storage space; a robot that, at least, conveys a wafer storage container from the first inspection unit to the cleaning unit and conveys a wafer storage container from the cleaning unit to the second inspection unit; and a control unit that controls the robot, in which in a case where it is determined on the basis of a result of inspection by the first inspection unit that the wafer storage container is in a usable state, the control unit controls the robot so as to convey the wafer storage container from the first inspection unit to the cleaning unit, and in a case where it is determined on the basis of the result of the inspection by the first inspection unit determined that the wafer storage container is not in the usable state, the control unit controls the robot so as to convey the wafer storage container from the first inspection unit to a position different from the cleaning unit.

In addition, a wafer storage container cleaning device according to an aspect of the present embodiment includes: a casing that includes therein a cleaning unit that cleans at least a wafer storage container, and a robot that conveys the wafer storage container; a load port that is provided across an inside and an outside of the casing; a first inspection unit that is provided inside the casing in the load port and inspects a flange portion of the wafer storage container; and a control unit that controls the robot, in which the control unit controls the robot so as to convey the wafer storage container inspected by the first inspection unit from the load port to the cleaning unit.

In addition, a wafer storage container cleaning method according to an aspect of the present embodiment includes: a process of performing a first inspection for inspecting a state of a grip target portion of a wafer storage container; a process of cleaning a storage space of the wafer storage container for which the first inspection has been completed; and a process of performing a second inspection for inspecting a state of the storage space of the wafer storage container for which cleaning of the storage space has been completed, in which on the basis of an inspection result in the process of performing the first inspection, the process of cleaning the storage space is performed only on the wafer storage container for which it is determined that the wafer storage container is in a usable state.

According to an aspect of the present embodiment, it is possible to inspect the wafer storage container and efficiently clean the wafer storage container.

Hereinafter, embodiments of a wafer storage container cleaning device and a wafer storage container cleaning method disclosed in the present application will be described in detail with reference to the accompanying drawings. Note that the wafer storage container cleaning device and the wafer storage container cleaning method disclosed in the present application are not limited to the following embodiments. Note that in the following embodiment, a case where the wafer storage container to be cleaned is a FOUP will be described, but the wafer storage container to be cleaned is not limited thereto. For example, the wafer storage container to be cleaned may be a FOSB.

### Embodiment

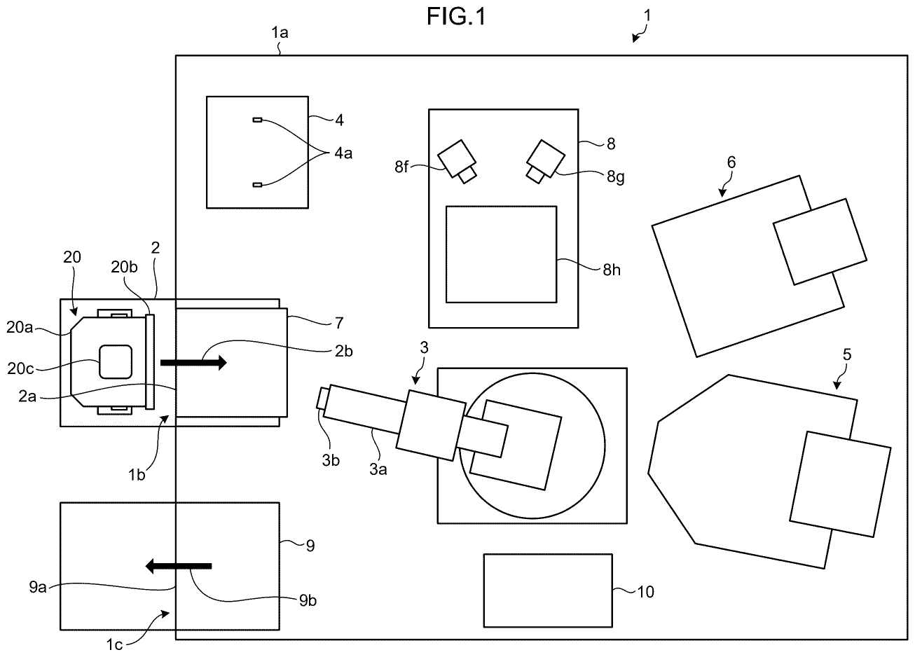

FIG. 1 is a plan view illustrating an example of a schematic configuration of a wafer storage container cleaning device 1 according to an embodiment. The wafer storage container cleaning device 1 is provided, for example, in a factory that manufactures semiconductor wafers, and cleans wafer storage containers. As illustrated in FIG. 1, the wafer storage container cleaning device 1 includes a load port 2, a robot 3, a disassembly/connection stage 4, a cleaning chamber 5, a vacuum chamber 6, a first inspection unit 7, a second inspection unit 8, an unload port 9, and a control unit 10.

The robot 3, the disassembly/connection stage 4, the cleaning chamber 5, the vacuum chamber (vacuum-drying chamber) 6, the first inspection unit 7, the second inspection unit 8, and the control unit 10 are provided inside a casing 1a of the wafer storage container cleaning device 1. On the other hand, the load port 2 and the unload port 9 are provided across the inside and the outside of the casing 1a of the wafer storage container cleaning device 1.

The load port 2 loads a FOUP 20 to be cleaned, which is placed on a portion of the load port 2 outside the casing 1a, into the casing 1a. The FOUP 20 includes a FOUP main body (shell) 20a and a door (lid) 20b. A space (storage space) for storing the semiconductor wafer is formed inside the FOUP main body 20a, and the door 20b can be disassembled/connected to the FOUP main body 20a. The storage space of the FOUP main body 20a communicates with the opening of the FOUP main body 20a and is located inside the opening of the FOUP main body 20a. In addition, the FOUP main body 20a is provided with a flange 20c. The flange 20c is a portion that is gripped (held) when the FOUP 20 is conveyed by an overhead hoist transport (OHT), the robot 3, or the like. Note that the OHT grips not only the flange 20c but also the bottom surface of the FOUP 20. The flange 20c is an example of a grip target portion.

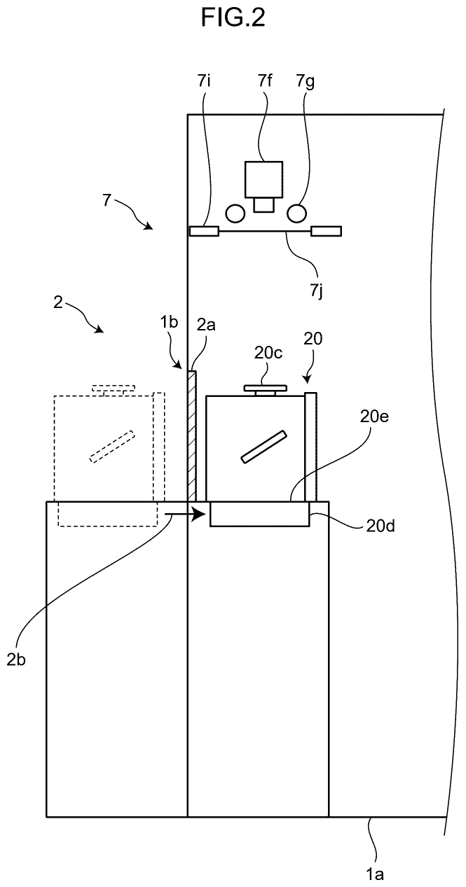

For example, the FOUP 20 conveyed in a state where the flange 20c is gripped by the OHT is placed on the portion of the load port 2 outside the casing 1a. When the FOUP 20 is placed on the load port 2 in this manner, a shutter 2a provided in an opening 1b of the casing 1a rises. Accordingly, the FOUP 20 can be loaded into the casing 1a from the opening 1b. That is, the FOUP 20 can be loaded into the wafer storage container cleaning device 1. FIG. 2 is a side view illustrating an example of the load port 2 and the first inspection unit 7 according to the embodiment. Then, as illustrated in FIG. 2, the FOUP 20 is slid in the direction indicated by an arrow 2b by a slide device 20d of the load port 2. Accordingly, the FOUP 20 is loaded into the casing 1a. An example of sliding by the slide device 20d will be described. For example, a pin provided in the slide device 20d is inserted into a hole provided in a bottom portion (placement surface) 20e of the FOUP 20, whereby the placement surface 20e of the FOUP 20 is fixed to the slide device 20d. Then, in such a state, the slide device 20d is slid in the direction of the arrow 2b, so that the FOUP 20 is slid together. Accordingly, the FOUP 20 is placed on a predetermined portion of the load port 2 inside the casing 1a. When the FOUP 20 is loaded into the casing 1a in this manner, the shutter 2a descends and the opening 1b of the casing 1a is closed. The slide device 20d descends to a position lower than the lower end of the shutter 2a (the placement surface 20e of the FOUP 20) together with the pin, and returns to the original position outside the casing 1a.

Returning to FIG. 1, the robot 3 conveys the FOUP 20 to each unit in the state of gripping the flange 20c of the FOUP 20. The robot 3 includes a robot arm 3a and a robot hand 3b. The robot 3 conveys the FOUP 20 to each unit by expanding/contracting or rotationally moving the robot arm 3a in a state where the flange 20c is gripped by the robot hand 3b.

The disassembly/connection stage 4 disassembles the FOUP 20 into the FOUP main body 20a and the door 20b, and connects the FOUP main body 20a and the door 20b. A latch key 4a is provided on the disassembly/connection stage 4. When the latch key 4a is rotated in the state of being inserted into a latch hole provided in the door 20b of the FOUP 20, the FOUP 20 is disassembled (separated) into the FOUP main body 20a and the door 20b, or the FOUP main body 20a and the door 20b are connected.

The cleaning chamber 5 is a chamber for cleaning the FOUP 20. For example, the cleaning chamber 5 cleans at least a storage space, which stores wafers, in the entire FOUP 20. The cleaning chamber 5 is an example of a cleaning unit. For example, the cleaning chamber 5 includes a cleaning chamber main body and a lid portion. The cleaning chamber main body has an opening on the upper side, and the FOUP main body 20a is loaded into the cleaning chamber main body from the opening. Then, a first holding unit that holds the loaded FOUP main body 20a is provided inside the cleaning chamber main body. In addition, the lid portion is provided above the cleaning chamber main body, and is opened and closed with respect to the opening of the cleaning chamber main body by the operation of an air cylinder. A second holding unit capable of holding the door 20b is provided inside the lid portion.

In addition, inside the cleaning chamber main body, a nozzle to which a liquid used when cleaning the FOUP main body 20a and the door 20b is supplied is provided. In addition, inside the cleaning chamber main body, a rotation unit that rotates the FOUP main body 20a and the door 20b held by the first holding unit and the second holding unit is provided. The cleaning processing is performed on the FOUP 20 by jetting liquid from the nozzle to the FOUP main body 20a and the door 20b rotated by the rotation unit. In addition, an air blow nozzle that injects gas is provided inside the cleaning chamber main body, and after the cleaning processing with the liquid, gas from the air blow nozzle is jetted to the FOUP main body 20a and the door 20b, so that the FOUP main body 20a and the door 20b are dried. Note that the FOUP main body 20a and the door 20b are rotated by the rotation unit also during drying processing with the gas from the air blow nozzle. In addition, the liquid attached to the FOUP main body 20a and the door 20b may be dried by the rotation by the rotation unit without jetting the gas from the air blow nozzle.

The vacuum chamber 6 is a chamber for vacuum-drying the FOUP 20. Inside the vacuum chamber 6, a holding unit that holds the FOUP main body 20a and the door 20b conveyed into the vacuum chamber 6, a halogen lamp, and a turbo molecular pump capable of vacuuming the inside of the vacuum chamber 6 are provided. In a state where the FOUP main body 20a and the door 20b are held by the holding unit, the vacuum chamber 6 vacuum-dries the FOUP main body 20a and the door 20b by heating the inside of the vacuum chamber 6 with the halogen lamp while being evacuated by the turbo molecular pump.

As illustrated in FIG. 2, the first inspection unit 7 inspects the state of the flange 20c of the FOUP 20 to be cleaned loaded into the portion of the load port 2 inside the casing 1a. For example, a camera 7f and an illumination 7g of the first inspection unit 7 are provided above a portion of the load port 2 inside the casing 1a. The illumination 7g is provided at a position where the entire flange 20c of the FOUP 20 placed on the load port 2 can be illuminated with light. Then, the illumination 7g illuminates the entire flange 20c with light through a measurement window 7j formed in a predetermined portion of a top plate 7i of the first inspection unit 7. As the illumination 7g, for example, a ring illumination is used. In addition, as illustrated in FIG. 2, the camera 7f is provided at a position where the entire flange 20c of the FOUP 20 placed on the load port 2 is in the field of view, and images the flange 20c via the measurement window 7j.

The above-described inspection by the first inspection unit 7 is referred to as a first inspection. For example, in the first inspection, the first inspection unit 7 determines whether or not the flange 20c is usable, by determining whether or not the shape of the flange 20c falls within the standard. Here, a case where the flange 20c is usable refers to, for example, a case where the shape of the flange 20c falls within the standard, and the robot 3, the OHT, or the like can grip the flange 20c without dropping it. On the other hand, a case where the flange 20c is unusable indicates a state where the shape of the flange 20c does not fall within the standard. In such a state, for example, there is a possibility that the flange 20c cannot be normally gripped by the robot 3, the OHT, or the like (including a case where the flange 20c and the FOUP 20 are inclined although the flange 20c can be gripped). In addition, in a case where the shape of the flange 20c greatly deviates from the standard (including a case where damage such as a crack occurs in a part of the flange 20c), there is a possibility that the flange falls off from the robot 3, the OHT, or the like although the flange can be gripped.

Note that in the first inspection, the determination is not limited to whether or not the shape of the flange 20c falls within a predetermined standard, and whether the flange 20c is usable may be determined based on whether or not the size of the flange 20c is smaller than a predetermined arbitrary size. That is, in the first inspection, in a case where the size of the flange 20c is smaller than the predetermined size (reference data), it is determined that the flange cannot be gripped by the robot 3 or the OHT, or there is a possibility of falling off, and thus, it is determined that the flange is “unusable”. The predetermined size may be set for each type of the FOUP 20 to be processed by the wafer storage container cleaning device 1, or may be set in common for all types of the FOUPs 20 to be processed by the wafer storage container cleaning device 1.

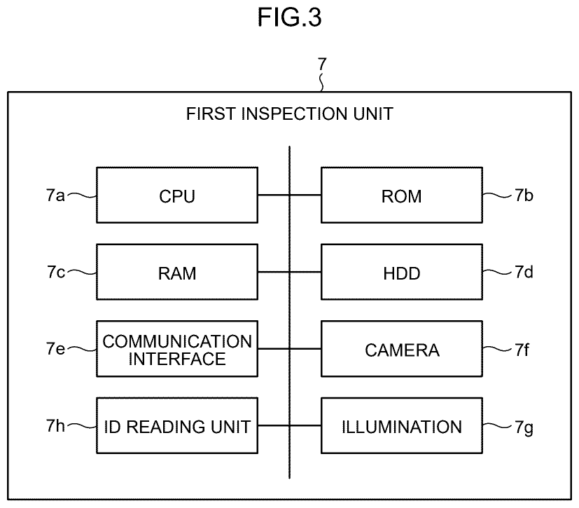

FIG. 3 is a diagram illustrating an example of a configuration of the first inspection unit 7 according to the embodiment. As illustrated in FIG. 3, the first inspection unit 7 includes a central processing unit (CPU) 7a, a read only memory (ROM) 7b, a random access memory (RAM) 7c, a hard disk drive (HDD) 7d, a communication interface 7e, the camera 7f, the illumination 7g, and an ID reading unit 7h. These are connected via an internal bus.

The CPU 7a executes various types of processing while using the storage area of the RAM 7c as a temporary storage area of data used for various types of processing. The ROM 7b and the HDD 7d store programs for executing various types of processing, and various databases, various tables, and the like used when executing various types of processing.

The communication interface 7e is an interface for communicating with a communication interface 10e described later of the control unit 10. For example, the communication interface 7e is a network interface card or the like.

The illumination 7g is provided at a position where the flange 20c of the FOUP 20 placed on the predetermined portion of the load port 2 inside the casing 1a can be illuminated with light from directly above (see FIG. 2). In addition, the camera 7f is provided at a position where the flange 20c of the FOUP 20 placed on the predetermined portion of the load port 2 inside the casing 1a can be imaged from directly above (see FIG. 2). The camera 7f images the flange 20c, and transmits, to the CPU 7a, image data obtained by imaging the flange 20c. The CPU 7a performs the above-described first inspection by executing image processing on the image data. Note that, in order to execute image processing on the image data obtained by imaging the flange 20c of the FOUP 20 placed on the predetermined portion of the load port 2 inside the casing 1a, “the predetermined portion of the load port 2 inside the casing 1a” may be included as a component of the first inspection unit 7. The image processing executed by the CPU 7a will be described later.

The ID reading unit 7h reads an identification (ID), which is identification information of the FOUP 20, provided in the FOUP 20. The ID reading unit 7h is an example of a reading unit. For example, the ID reading unit 7h is a barcode scanner (barcode reader), reads a barcode indicating an individual identification number of the FOUP 20 as the ID of the FOUP 20, and transmits, to the CPU 7a, the individual identification number indicated by the read barcode. In addition, for example, the ID reading unit 7h may be a reader that reads the individual identification number of the FOUP 20 output as the ID of the FOUP 20 from the RF tag provided in the FOUP 20. Then, the ID reading unit 7h transmits the read individual identification number to the CPU 7a. When receiving the individual identification number, the CPU 7a controls the communication interface 7e to transmit the received individual identification number to the communication interface 10e of the control unit 10. Accordingly, the communication interface 7e transmits the individual identification number to the communication interface 10e of the control unit 10.

Returning to the description of FIG. 1, the second inspection unit 8 inspects the state of the storage space of the FOUP 20 cleaned and vacuum-dried by the cleaning chamber 5 and the vacuum chamber 6.

The above-described inspection by the second inspection unit 8 is referred to as a second inspection. For example, in the second inspection, the second inspection unit 8 determines whether or not the storage space of the FOUP 20 is usable, by determining whether or not the shape of the storage space of the FOUP 20 falls within the standard. Here, a case where the storage space of the FOUP 20 is usable refers to, for example, a case where a bump position provided in the storage space of the FOUP 20 and the shape of a shelf on which the wafer is placed fall within the standard, and the wafer can be normally stored in the storage space of the FOUP 20. On the other hand, a case where the storage space of the FOUP 20 is unusable refers to, for example, a case where the bump position provided in the storage space of the FOUP 20 and the shape of the shelf on which the wafer is placed do not fall within the standards, and the wafer cannot be normally stored in the storage space of the FOUP 20, or there is a possibility that the wafer falls off the shelf although the wafer can be stored. Alternatively, a case where the storage space of the FOUP 20 is unusable refers to a case where the shape of the shelf does not fall within the standard (for example, a pitch between vertically adjacent shelves is excessively narrow), and there is a possibility that the upper and lower wafers come into contact with each other.

Note that in the second inspection, the determination is not limited to whether the shape of the storage space of the FOUP 20 falls within the predetermined standard, and the determination as to whether the FOUP 20 is usable may be made based on whether or not a deviation amount from a predetermined arbitrary reference value (reference data) falls within an allowable range. That is, in the second inspection, for example, in a case where the deviation amount of the bump position from the predetermined reference position exceeds the allowable range, the wafer cannot be stored, or there is a possibility that, although the wafer can be stored, the wafer falls off, or the wafers come into contact with each other, and it is determined that the storage space is “unusable”. The predetermined reference value and the allowable range may be set for each type of the FOUP 20 to be processed by the wafer storage container cleaning device 1, or may be set in common for all types of the FOUPs 20 to be processed by the wafer storage container cleaning device 1.

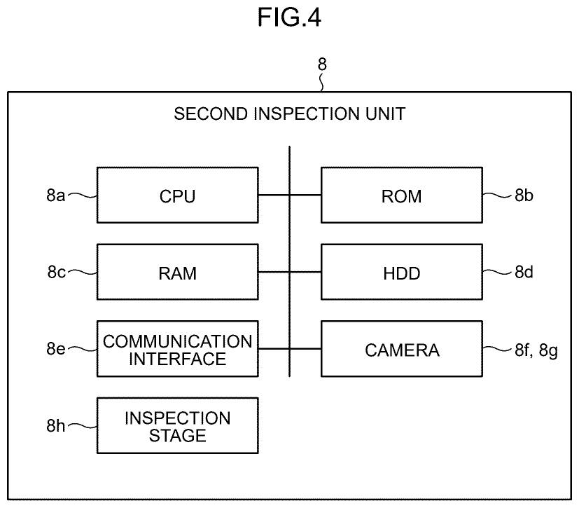

FIG. 4 is a diagram illustrating an example of a configuration of the second inspection unit 8 according to the embodiment. As illustrated in FIG. 4, the second inspection unit 8 includes a CPU 8a, a ROM 8b, a RAM 8c, an HDD 8d, a communication interface 8e, two cameras 8f and 8g, and an inspection stage 8h. Among them, the CPU 8a, the ROM 8b, the RAM 8c, the HDD 8d, the communication interface 8e, and the two cameras 8f and 8g are connected via an internal bus.

The CPU 8a executes various types of processing while using the storage area of the RAM 8c as a temporary storage area of data used for various types of processing. The ROM 8b and the HDD 8d store programs for executing various types of processing, and various databases, various tables, and the like used when executing various types of processing.

The communication interface 8e is an interface for communicating with a communication interface 10e described later of the control unit 10. For example, the communication interface 8e is a network interface card.

The cameras 8f and 8g are provided at positions facing the opening portion of the FOUP main body 20a placed on the inspection stage 8h. In addition, the cameras 8f and 8g are provided at positions where the storage space of the FOUP main body 20a placed on the inspection stage 8h can be imaged. The cameras 8f and 8g image the storage space of the FOUP 20, and transmit, to the CPU 8a, image data obtained by imaging the storage space of the FOUP main body 20a. The CPU 8a performs the above-described second inspection by executing image processing on the image data. The image processing executed by the CPU 8a will be described later.

On the inspection stage 8h, the FOUP main body 20a is placed by the robot 3 such that the flange 20c of the FOUP main body 20a faces upward and the opening faces the cameras 8f and 8g. At this time, the FOUP main body 20a is positioned by a positioning pin provided on the inspection stage 8h, and the FOUP main body 20a is placed on the inspection stage 8h.

The inspection stage 8h can be moved up and down by a lifting mechanism (not illustrated), and the positional relationship between the opening of the FOUP main body 20a and the cameras 8f and 8g changes relatively. Accordingly, the visual field ranges of the cameras 8f and 8g sequentially and relatively move in the entire storage space of the FOUP main body 20a as an imaging target, and the cameras 8f and 8g sequentially capture images.

Returning to the description of FIG. 1, the unload port 9 unloads, to the outside of the casing 1a, the cleaned and vacuum-dried FOUP 20 placed on the portion of the unload port 9 inside the casing 1a by the robot 3.

For example, the FOUP 20 conveyed by the robot 3 is placed on a portion of the unload port 9 inside the casing 1a. When the FOUP 20 is placed on the unload port 9 in this manner, a shutter 9a provided in an opening 1c of the casing 1a rises. Accordingly, the FOUP 20 can be unloaded from the opening 1c to the outside of the casing 1a. That is, the FOUP 20 can be unloaded to the outside of the wafer storage container cleaning device 1. Then, the FOUP 20 is slid in the direction indicated by an arrow 9b by the slide device of the unload port 9 (having a mechanism similar to that of the slide device of the load port 2), whereby the FOUP 20 is unloaded to the outside of the casing 1a. When the FOUP 20 is unloaded to the outside of the casing 1a in this manner, the shutter 9a descends and the opening 1c of the casing 1a is closed.

Here, on the basis of the determination results by the first inspection unit 7 and the second inspection unit 8, in a case where the FOUP 20 is usable, the control unit 10 transmits a signal indicating that the FOUP is to be conveyed to the “usable FOUP stocker” to an external device (a server that centrally manages all FOUPs to be described later). Based on this signal, a conveyance device such as the OHT in the factory is controlled, and the FOUP 20 is conveyed to the “usable FOUP stocker”. On the other hand, on the basis of the determination results by the first inspection unit 7 and the second inspection unit 8, in a case where the FOUP 20 is unusable, the control unit 10 transmits a signal indicating that the FOUP is to be conveyed to the “unusable FOUP stocker” to the external device. Based on this signal, the conveyance device in the factory is controlled, and the FOUP 20 is conveyed to the “unusable FOUP stocker”. Accordingly, only the usable FOUP 20 is conveyed to the “usable FOUP stocker”, and only the unusable FOUP 20 is conveyed to the “unusable FOUP stocker”. The “usable FOUP stocker” is an example of a first stocker. In addition, the “unusable FOUP stocker” is an example of a second stocker.

Alternatively, the control unit 10 may rewrite the information regarding the RF tag included in the FOUP 20 on the basis of the determination results of the first inspection unit 7 and the second inspection unit 8, add, for each FOUP 20, information indicating whether the FOUP is the FOUP to be conveyed to the “usable FOUP stocker” or the FOUP to be conveyed to the “unusable FOUP stocker”, and convey the FOUP to each stocker by the conveyance device in the factory, on the basis of the information.

As described above, the control unit 10 transmits, to the external device, the signal indicating to which stocker the FOUP 20 is to be conveyed. In this case, although it is the external device that directly controls the conveyance of the FOUP 20, transmission of a conveyance instruction of the FOUP 20 to such another control unit (transmission of a signal indicating a conveyance destination) also corresponds to control so as to convey the FOUP (wafer storage container) 20 to the first stocker or the second stocker.

The control unit 10 controls the operation of the entire wafer storage container cleaning device 1. For example, the control unit 10 controls the load port 2, the robot 3, the disassembly/connection stage 4, the cleaning chamber 5, the vacuum chamber 6, the first inspection unit 7, the second inspection unit 8, and the unload port 9 to operate the load port 2, the robot 3, the disassembly/connection stage 4, the cleaning chamber 5, the vacuum chamber 6, the first inspection unit 7, the second inspection unit 8, and the unload port 9 as described above.

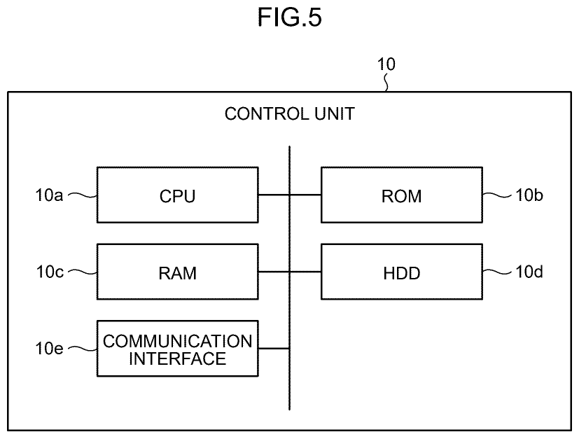

FIG. 5 is a diagram illustrating an example of a configuration of the control unit 10 according to the embodiment. As illustrated in FIG. 5, the control unit 10 is a computer (controller) including a CPU 10a, a ROM 10b, a RAM 10c, an HDD 10d, and the communication interface 10e. These are connected via an internal bus.

The CPU 10a executes various types of processing while using the storage area of the RAM 10c as a temporary storage area of data used for various types of processing. The processing executed by the CPU 10a will be described later. The ROM 10b and the HDD 10d store programs for executing various types of processing, and various databases, various tables, and the like used when executing various types of processing.

In the present embodiment, for example, the ROM 10b or the HDD 10d stores in advance an inspection table in which a record in which an individual identification number (ID) of the FOUP, first inspection data corresponding to the FOUP indicated by the ID, and second inspection data corresponding to the FOUP indicated by the ID are registered in association with each other is registered for each ID.

The registered content of the inspection table will be specifically described. For example, reference data regarding the shape of the flange varies depending on the type of the FOUP. The reference data regarding the shape of the flange is data indicating the shape of the flange, data having a constant width, and data conforming to the standard. In the present embodiment, the reference data related to the shape of the flange corresponding to the type of the FOUP indicated by the ID is registered as the first inspection data in the inspection table in association with the ID. The first inspection data is used in the first inspection by the first inspection unit 7.

In addition, for example, reference data regarding the shape of the storage space of the FOUP varies depending on the type of the FOUP. The reference data regarding the shape of the storage space of the FOUP is data indicating the shape of the storage space of the FOUP, data having a constant width, and data conforming to the standard. In the present embodiment, the reference data related to the shape of the storage space of the FOUP corresponding to the type of the FOUP indicated by the ID is registered as the second inspection data in the inspection table in association with the ID. The second inspection data is used in the second inspection by the second inspection unit 8.

The communication interface 10e is an interface for communicating with the above-described communication interfaces 7e and 8e and also communicating with the external device connected to the wafer storage container cleaning device 1 via a network. For example, the communication interface 10e is a network interface card.

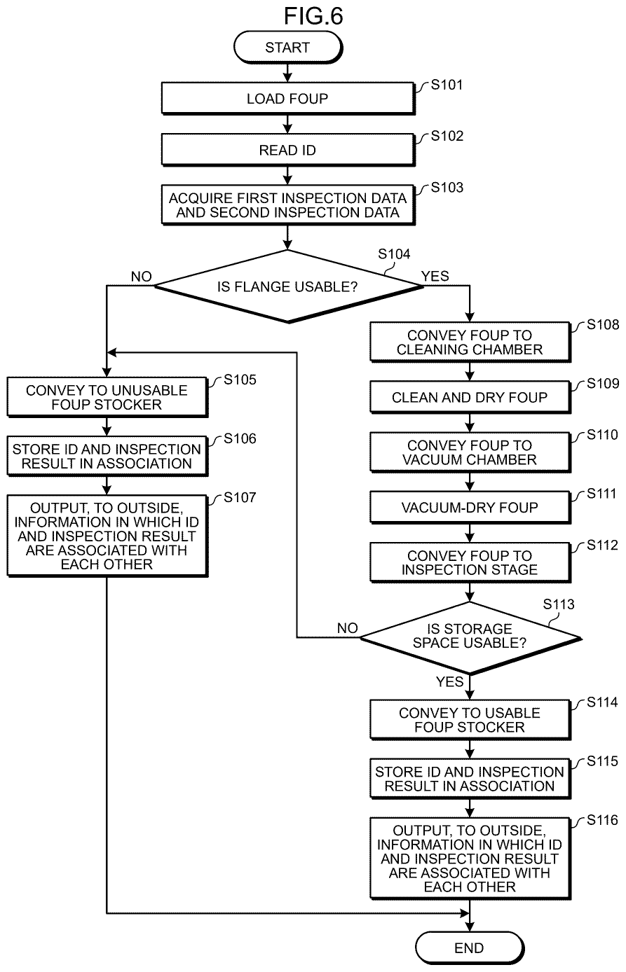

Next, an example of the processing executed by the wafer storage container cleaning device 1 will be described. FIG. 6 is a flowchart illustrating a flow of an example of processing executed by the wafer storage container cleaning device 1 according to the embodiment. The processing illustrated in FIG. 6 is executed in a case where the FOUP 20 to be cleaned is placed on the portion of the load port 2 outside the casing 1a. Note that the processing illustrated in FIG. 6 is, for example, processing executed by each unit under the control of the control unit 10.

As illustrated in FIG. 6, first, the load port 2 loads, into the casing 1a, the FOUP 20 placed on a portion of the load port 2 outside the casing 1a (step S101).

Next, the ID reading unit 7h of the first inspection unit 7 reads the individual identification number (ID) of the FOUP 20 placed on a predetermined portion of the load port 2 inside the casing 1a (step S102). The read individual identification number is transmitted to the control unit 10 as described above. Then, when receiving the individual identification number, the communication interface 10e of the control unit 10 transmits the received ID to the CPU 10a.

Then, when receiving the ID, the CPU 10a of the control unit 10 refers to the registered content of the inspection table described above, identifies the first inspection data and the second inspection data associated with the received ID, and acquires the identified first inspection data and second inspection data (step S103). The CPU 10a controls the communication interface 10e to transmit the acquired first inspection data to the first inspection unit 7. In addition, the CPU 10a controls the communication interface 10e to transmit the acquired second inspection data to the second inspection unit 8. Accordingly, the CPU 7a of the first inspection unit 7 can perform processing in the first inspection using the first inspection data transmitted from the communication interface 10e. In addition, the CPU 8a of the second inspection unit 8 can perform processing in the second inspection using the second inspection data transmitted from the communication interface 10e.

Next, the CPU 7a of the first inspection unit 7 executes image processing on the image data obtained by imaging the flange 20c by the camera 7f, and determines whether or not the flange 20c is usable, by using the first inspection data (step S104).

An example of specific processing in step S104 will be described. For example, in step S104, the CPU 7a executes image processing for obtaining the shape of the flange 20c drawn in the image data, on the image data obtained by the camera 7f. Then, by determining whether or not the shape of the flange 20c obtained by the image processing falls within the standard related to the shape of the flange indicated by the first inspection data, the CPU 7a determines whether or not the flange 20c is usable.

In a case where it is determined that the flange 20c is unusable (step S104: No), the CPU 10a of the control unit 10 performs control so as to convey the FOUP 20 to the “unusable FOUP stocker” (step S105).

An example of specific processing in step S105 will be described. For example, in step S105, the CPU 10a controls the robot 3 so as to convey the FOUP 20 placed on the predetermined portion of the load port 2 inside the casing 1a to a predetermined portion of the unload port 9 inside the casing 1a. As a result, the FOUP 20 is placed on the predetermined portion of the unload port 9 inside the casing 1a by the robot 3. Then, the CPU 10a controls the unload port 9 such that the FOUP 20 is unloaded to the outside of the casing 1a. At this time, the CPU 10a transmits a signal for conveying the FOUP 20 to the “unusable FOUP stocker” to the external device. Accordingly, a conveyance device such as the OHT in the factory controlled by the external device conveys the FOUP 20 to the “unusable FOUP stocker”.

Next, the CPU 10a stores the ID and the result of the first inspection in the HDD 10d in association with each other (step S106). Note that in a case where the result of the past first inspection is stored in the HDD 10d in association with the ID, the CPU 10a stores, as a history, the result of the current first inspection in the HDD 10d in association with the ID. The result of the first inspection includes the shape of the flange 20c obtained by image processing and information indicating whether or not the flange 20c is usable. In a case where these pieces of information stored in the HDD 10d are displayed on a display, a user can easily grasp a state where the flange 20c of the FOUP 20 indicated by the ID changes in time series. Therefore, according to the present embodiment, it is possible to cause the HDD 10d to store information that allows the user to easily grasp the state of the flange 20c of the FOUP 20 indicated by the ID that changes in time series. By grasping the temporal change of the flange 20c to be inspected, for example, the average life can be grasped for each type of the FOUP, the cleaning processing of the FOUP in a reliably usable state can be performed, and the FOUP can be conveyed to the “usable FOUP stocker”.

Then, the CPU 10a controls the communication interface 10e so as to output, to the external device, information in which the ID and the result of the first inspection are associated with each other (step S107), and ends the processing illustrated in FIG. 6. Here, the external device is, for example, a server that centrally manages all the FOUPs 20 in the factory. When receiving the information in which the ID and the result of the first inspection are associated with each other, such an external device causes a storage unit such as an HDD to store, as a history, the result of the first inspection in association with the ID. Then, the external device causes a display to display the information stored in the HDD. At this time, the user can easily grasp the state of the flange 20c of the FOUP 20 indicated by the ID displayed on the display. The information in which the ID and the result of the first inspection are associated with each other is an example of the first information.

On the other hand, in a case where it is determined that the flange 20c is usable (step S104: Yes), the CPU 10a of the control unit 10 controls the robot 3 so as to convey the FOUP 20 from the first inspection unit 7 to the cleaning chamber 5 via the disassembly/connection stage 4 (step S108).

An example of specific processing in step S108 will be described. In step S108, first, the CPU 10a controls the robot 3 so as to convey, to the disassembly/connection stage 4, the FOUP 20 placed on the predetermined portion of the load port 2 inside the casing 1a. As a result, the FOUP 20 conveyed to the disassembly/connection stage 4 is disassembled into the FOUP main body 20a and the door 20b by the disassembly/connection stage 4. Then, the CPU 10a controls the robot 3 so as to convey the FOUP main body 20a into the cleaning chamber main body of the cleaning chamber 5. In addition, the CPU 10a controls the robot 3 so as to convey the door 20b to the lid portion of the cleaning chamber 5. Accordingly, the first holding unit provided inside the cleaning chamber main body of the cleaning chamber 5 holds the FOUP main body 20a, and the second holding unit provided inside the lid portion of the cleaning chamber 5 holds the door 20b. Note that the height of the cleaning chamber main body of the cleaning chamber 5 is a height at which the FOUP main body 20a and the door 20b do not come into contact with each other in a state where the door 20b is provided in the second holding unit inside the lid portion of the cleaning chamber 5 and the first holding unit of the cleaning chamber main body holds the FOUP main body 20a and closes the lid portion.

Then, the cleaning chamber 5 cleans and dries the FOUP 20 (step S109). Specifically, in step S109, the cleaning processing is performed on the FOUP 20 by jetting liquid from the nozzle to the FOUP main body 20a and the door 20b rotated by the rotation unit. Further, after the cleaning processing, gas from the air blow nozzle is jetted to the FOUP main body 20a and the door 20b, so that the FOUP main body 20a and the door 20b are dried.

Then, the CPU 10a controls the robot 3 so as to convey the FOUP main body 20a and the door 20b from the cleaning chamber 5 to the vacuum chamber 6 (step S110). As a result, the FOUP main body 20a and the door 20b are conveyed into the vacuum chamber 6 by the robot 3.

Then, the vacuum chamber 6 vacuum-dries the FOUP main body 20a and the door 20b (step S111). In the vacuum chamber 6, the FOUP main body 20a and the door 20b placed in the vacuum chamber 6 are vacuum-dried by heating with a halogen lamp while being vacuumed by a turbo molecular pump, and water droplets that cannot be dried by drying by an air blow nozzle in the cleaning chamber 5, remaining attached substances, and the like are removed.

Then, the CPU 10a controls the robot 3 so as to convey the FOUP main body 20a from the vacuum chamber 6 to the inspection stage 8h of the second inspection unit 8 (step S112). As a result, the FOUP main body 20a is positioned with respect to the inspection stage 8h by the robot 3 and placed on the inspection stage 8h. Note that at this time, the door 20b is placed by the robot 3 such that a latch hole abuts on the disassembly/connection stage 4.

Next, the CPU 8a of the second inspection unit 8 executes image processing on the image data obtained by imaging the storage space of the FOUP main body 20a by the cameras 8f and 8g, and determines whether or not the storage space of the FOUP main body 20a is usable, by using the second inspection data (step S113).

An example of specific processing in step S113 will be described. For example, in step S113, the CPU 8a executes image processing for obtaining the shape of the storage space of the FOUP main body 20a drawn in the image data, on the image data obtained by the cameras 8f and 8g. Then, by determining whether or not the shape of the storage space obtained by the image processing falls within the standard related to the shape of the storage space indicated by the second inspection data, the CPU 8a determines whether or not the storage space of the FOUP main body 20a is usable.

In a case where it is determined that the storage space of the FOUP main body 20a is unusable (step S113: No), the CPU 10a proceeds to step S105. Note that, in a case where a negative determination is made in step S113 (step S113: No), in addition to the processing in step S105 described above, the CPU 10a controls the robot 3 so as to convey the FOUP main body 20a placed on the inspection stage 8h to the disassembly/connection stage 4. As a result, the door 20b already placed on the disassembly/connection stage 4 and the FOUP main body 20a conveyed to the disassembly/connection stage 4 after completion of the second inspection are connected by the disassembly/connection stage 4. Then, the CPU 10a controls the robot 3 so as to convey the FOUP 20 located on the disassembly/connection stage 4 to the predetermined portion of the unload port 9 inside the casing 1a. As a result, the FOUP 20 is placed on the predetermined portion of the unload port 9 inside the casing 1a by the robot 3. Then, the CPU 10a controls the unload port 9 such that the FOUP 20 is unloaded to the outside of the casing 1a. At this time, the CPU 10a transmits a signal for conveying the FOUP 20 to the “unusable FOUP stocker” to the external device. Accordingly, a conveyance device such as the OHT in the factory controlled by the external device conveys the FOUP 20 to the “unusable FOUP stocker”.

In addition, in a case where a negative determination is made in step S113 (step S113: No), in step S106, the CPU 10a further executes the following processing in addition to the processing in step S106 described above. For example, the CPU 10a stores the ID and the result of the second inspection in the HDD 10d in association with each other. Note that in a case where the result of the past second inspection is stored in the HDD 10d in association with the ID, the CPU 10a stores, as a history, the result of the current second inspection in the HDD 10d in association with the ID. The result of the second inspection includes the shape of the storage space of the FOUP main body 20a obtained by the image processing, and information indicating whether or not the storage space of the FOUP main body 20a is usable. In a case where these pieces of information stored in the HDD 10d are displayed on a display, the user can easily grasp a state where the storage space of the FOUP main body 20a of the FOUP 20 indicated by the ID changes in time series. Therefore, according to the present embodiment, it is possible to cause the HDD 10d to store information that allows the user to easily grasp the state of the storage space of the FOUP main body 20a of the FOUP 20 indicated by the ID changing in time series. By grasping the temporal change of the FOUP main body 20a to be inspected, for example, the average life can be grasped for each type of the FOUP, the cleaning processing of the FOUP in a reliably usable state can be performed, and the FOUP can be conveyed to the “usable FOUP stocker”. Alternatively, in a case where the inspection result is changed by the processing in the process before being loaded into the wafer storage container cleaning device 1, when the FOUP subjected to the similar processing next is loaded into the wafer storage container cleaning device 1, the processing content performed in the wafer storage container cleaning device 1 can be changed, for example, the cleaning processing time or the type of cleaning liquid in the cleaning chamber 5 is changed, or the vacuum-drying processing time in the vacuum chamber 6 is changed.

In addition, in a case where a negative determination is made in step S113 (step S113: No), in step S107, the CPU 10a further executes the following processing in addition to the processing in step S107 described above. For example, the CPU 10a controls the communication interface 10e so as to output, to the external device, information in which the ID and the result of the second inspection are associated with each other. Here, when receiving the information in which the ID and the result of the second inspection are associated with each other, the external device causes a storage unit such as an HDD to store, as a history, the result of the second inspection in association with the ID. Then, the external device causes a display to display the information stored in the HDD. At this time, the user can easily grasp the state of the storage space of the FOUP main body 20a of the FOUP 20 indicated by the ID displayed on the display. The information in which the ID and the result of the second inspection are associated with each other is an example of the second information.

As described above, the first inspection result and the second inspection result are stored in the server that centrally manages all the FOUPs of the external device. The conveyance device in the factory may be controlled on the basis of the data stored in the server. That is, in the first inspection result and the second inspection result, the FOUP determined to be “usable” and the FOUP determined to be “unusable” are conveyed to a common stocker without being distinguished from each other, and the conveyance device in the factory is controlled such that only the FOUP determined to be “usable” is used. In this case, the first stocker and the second stocker are virtually provided in the server. That is, on the basis of the results of the first inspection and the second inspection, the control unit 10 performs control so as to convey the “usable” FOUP to the virtually provided first stocker and convey the “unusable” FOUP to the virtually provided second stocker. In addition, as described above, by storing the first information and the second information, including the rewriting result of the RF tag, in the server, the first information and the second information may be stored separately in a virtual first stocker and a virtual second stocker in the server. Also in this case, all the FOUPs may be physically conveyed to the common stocker.

On the other hand, in a case where it is determined that the storage space of the FOUP main body 20a is usable (step S113: Yes), the CPU 10a performs control so as to convey the FOUP 20 to the “usable FOUP stocker” (step S114).

An example of specific processing in step S114 will be described. For example, in step S114, first, the CPU 10a controls the robot 3 so as to convey, to the disassembly/connection stage 4, the FOUP main body 20a placed on the inspection stage 8h. As a result, the door 20b already placed on the disassembly/connection stage 4 and the FOUP main body 20a conveyed to the disassembly/connection stage 4 after completion of the second inspection are connected by the disassembly/connection stage 4. Then, the CPU 10a controls the robot 3 so as to convey the FOUP 20 located on the disassembly/connection stage 4 to the predetermined portion of the unload port 9 inside the casing 1a. As a result, the FOUP 20 is placed on the predetermined portion of the unload port 9 inside the casing 1a by the robot 3. Then, the CPU 10a controls the unload port 9 such that the FOUP 20 is unloaded to the outside of the casing 1a. At this time, the CPU 10a transmits a signal for conveying the FOUP 20 to the “usable FOUP stocker” to the external device. Accordingly, a conveyance device such as the OHT conveys the FOUP 20 to the “usable FOUP stocker”.

Then, the CPU 10a executes the processing in steps S115 and S116, and ends the processing illustrated in FIG. 6. For example, in step S115, the CPU 10a executes processing similar to the processing in step S106 in a case where a negative determination is made in step S113 (step S113: No). In addition, in step S116, the CPU 10a executes processing similar to the processing in step S107 in a case where a negative determination is made in step S113 (step S113: No).

The wafer storage container cleaning device 1 according to the embodiment has been described above. In the present embodiment, the robot 3 conveys, at least, the FOUP 20 from the first inspection unit 7 to the cleaning chamber 5, and conveys the FOUP 20 from the cleaning chamber 5 to the second inspection unit 8 (in short, the FOUP 20 may be conveyed from the cleaning chamber 5 to the second inspection unit 8 without passing through the vacuum chamber 6). Then, in a case where it is determined on the basis of the result of the first inspection by the first inspection unit 7 that the FOUP 20 (specifically, the flange 20c) is in a usable state, the control unit 10 controls the robot 3 so as to convey the FOUP 20 from the first inspection unit 7 to the cleaning chamber 5. In addition, in a case where it is determined on the basis of the result of the first inspection by the first inspection unit 7 that the FOUP 20 (specifically, the flange 20c) is not in the usable state, the control unit 10 controls the robot 3 so as to convey the FOUP 20 from the first inspection unit 7 to a position different from the cleaning chamber 5.

Therefore, in the wafer storage container cleaning device 1, the FOUP 20 that is in the usable state is cleaned, but it is not necessary to wastefully clean the FOUP 20 having the flange 20c that is not in the usable state. Therefore, according to the wafer storage container cleaning device 1 of the present embodiment, it is possible to inspect the FOUP 20 and efficiently clean the FOUP 20.

In addition, as described above, the OHT grips not only the flange 20c but also the bottom surface of the FOUP 20. Therefore, even in a case where the flange 20c is not in the usable state, the FOUP 20 rarely falls off from the OHT. However, in the wafer storage container cleaning device 1 according to the present embodiment, the robot 3 grips only the flange 20c when conveying the FOUP 20 or the FOUP main body 20a. In this regard, in the wafer storage container cleaning device 1 according to the present embodiment, before the process in which the FOUP 20 or the FOUP main body 20a is conveyed by the robot 3, the first inspection unit 7 inspects the state of the flange 20c. Then, in a case where the flange 20c is not in the usable state, the FOUP 20 is conveyed to the “unusable FOUP stocker” without shifting to the process in which the FOUP 20 or the FOUP main body 20a is conveyed by the robot 3. Therefore, according to the wafer storage container cleaning device 1 of the present embodiment, the FOUP 20 or the FOUP main body 20a can be more reliably and safely conveyed by the robot 3 in the wafer storage container cleaning device 1.

In addition, in a case where it is determined on the basis of the result of the second inspection by the second inspection unit 8 that the FOUP 20 (specifically, the storage space of the FOUP 20) is in the usable state, the control unit 10 performs control so as to convey the FOUP 20 to the “usable FOUP stocker”. In addition, in a case where it is determined on the basis of the result of the second inspection by the second inspection unit 8 that the FOUP 20 (specifically, the storage space of the FOUP 20) is not in the usable state, the control unit 10 performs control so as to convey the FOUP 20 to the “unusable FOUP stocker” different from the “usable FOUP stocker”.

Therefore, according to the wafer storage container cleaning device 1 of the present embodiment, the FOUP 20 in the usable state and the FOUP 20 in the unusable state can be physically/virtually divided. As a result, as the FOUP 20 that can appropriately store the wafers, the FOUP 20 in the usable state can be provided to a process after the FOUP 20 is unloaded from the wafer storage container cleaning device 1.

In addition, on the basis of the ID, the control unit 10 identifies the first inspection data used as a reference for determining whether or not the flange 20c of the FOUP 20 is usable when the first inspection unit 7 performs the inspection. In addition, on the basis of the ID, the control unit 10 identifies the second inspection data used as a reference for determining whether or not the storage space in the FOUP 20 is usable when the second inspection unit 8 performs the inspection.

As described above, according to the wafer storage container cleaning device 1 of the present embodiment, the first inspection data and the second inspection data are identified on the basis of the ID. Therefore, the appropriate first inspection data and second inspection data corresponding to the FOUP 20 to be cleaned can be more accurately identified.

In addition, the control unit 10 outputs, to the outside, information in which the ID is associated with the result of the first inspection by the first inspection unit 7 and information in which the ID is associated with the result of the second inspection by the second inspection unit 8.

Therefore, according to the wafer storage container cleaning device 1 according to the present embodiment, it is possible to output, to the outside, information capable of easily grasping the state of the flange 20c and the state of the storage space.

Note that both the first inspection unit 7 and the second inspection unit 8 include the CPU 7a and the CPU 8a, respectively, and perform image processing and determination. However, the present invention is not limited thereto, and the first inspection unit 7 and the second inspection unit 8 may perform only detection (imaging) of an inspection target, and the control unit 10 may perform inspection (image processing, determination). In this case, the communication interface 10e of the control unit 10 functions as an interface with the external device outside the wafer storage container cleaning device 1.

In addition, in the above embodiment, the cleaning unit exemplifies the cleaning chamber 5 in which the cleaning by the liquid and then the drying by the gas from the air blow nozzle are performed, but the present invention is not limited thereto, and only the cleaning by the liquid may be performed.

Note that in the above embodiment, after the inspection by the second inspection unit 8 is completed, in the disassembly/connection stage 4, the FOUP main body 20a and the door 20b are connected to each other, and are unloaded from the unload port 9 to the stocker from the wafer storage container cleaning device 1. However, the present invention is not limited thereto. In the wafer storage container cleaning device 1, a nitrogen gas may be injected through a purging hole provided in the bottom portion of the FOUP 20 to the inside (storage space) of the FOUP 20 in a state where the FOUP main body 20a and the door 20b are connected to each other, so as to perform the inspection for checking the sealability of the FOUP 20. This may be performed, for example, in the disassembly/connection stage or in the unload port 9. Alternatively, it may be performed on a temporary placing table (not illustrated) provided in the casing 1a.

In addition, the disassembly/connection stage is not necessarily provided only for disassembling and connecting the FOUP main body 20a and the door 20b, and for example, a plurality of buffer tables on which a plurality of FOUPs 20 waiting to be unloaded after all the processing by the wafer storage container cleaning device 1 are placed may be provided, and the latch key 4a may be provided in the plurality of buffer tables, so as to function as the disassembly/connection stage.

In addition, the example in which the FOUP 20 determined to be “not in the usable state” in the first inspection is conveyed to the unload port 9 which is a position different from the cleaning chamber 5 has been described, but the present invention is not limited thereto, and the FOUP may be conveyed to another place. For example, other places provided in the casing 1a, such as the plurality of disassembly/connection stages 4, the temporary placing table, and the buffer table described above, may be provided.

### Modification

Next, a modification of the above-described embodiment will be described. For example, in the above-described embodiment, a case has been described in which the camera 7f images the flange 20c of the FOUP 20 placed on the predetermined portion of the load port 2 inside the casing 1a. However, in the modification, the camera 7f may image the flange 20c of the FOUP 20 before the FOUP 20 is loaded into the casing 1a. That is, the camera 7f may image the flange 20c of the FOUP 20 placed on a predetermined portion of the load port 2 outside the casing 1a. Then, in a case where it is determined that the flange 20c is unusable (step S104: No), the CPU 10a of the control unit 10 may perform control so as to convey the FOUP 20 to the “unusable FOUP stocker” without loading the FOUP 20 into the casing 1a.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

1. A wafer storage container cleaning device comprising:
a first inspection unit that inspects a state of a grip target portion of a wafer storage container;
a cleaning unit that cleans at least a storage space in which a wafer is stored, in the wafer storage container;
a second inspection unit that inspects a state of the storage space;
a robot that, at least, conveys the wafer storage container from the first inspection unit to the cleaning unit and conveys the wafer storage container from the cleaning unit to the second inspection unit; and
a control unit that controls the robot, wherein
in a case where it is determined on a basis of a result of inspection by the first inspection unit that the wafer storage container is in a usable state, the control unit controls the robot so as to convey the wafer storage container from the first inspection unit to the cleaning unit, and in a case where it is determined on a basis of the result of the inspection by the first inspection unit that the wafer storage container is not in the usable state, the control unit controls the robot so as to convey the wafer storage container from the first inspection unit to a position different from that of the cleaning unit.

2. The wafer storage container cleaning device according to claim 1, wherein
in a case where it is determined on a basis of a result of inspection by the second inspection unit that the wafer storage container is in the usable state, the control unit controls so as to convey the wafer storage container to a first stocker, and in a case where it is determined on a basis of the result of the inspection by the second inspection unit that the wafer storage container is not in the usable state, the control unit controls so as to convey the wafer storage container to a second stocker different from the first stocker.

3. The wafer storage container cleaning device according to claim 1, further comprising:
a reading unit that reads identification information provided in the wafer storage container, wherein
the control unit identifies, on a basis of the identification information, first inspection data used as a reference for determining whether or not the grip target portion of the wafer storage container is usable when the first inspection unit performs inspection, and second inspection data used as a reference for determining whether or not the storage space of the wafer storage container is usable when the second inspection unit performs inspection.

4. The wafer storage container cleaning device according to claim 1, further comprising:
a reading unit that reads identification information provided in the wafer storage container, wherein
the control unit outputs, to an outside, first information in which the identification information is associated with the result of the inspection by the first inspection unit, and second information in which the identification information is associated with the result of the inspection by the second inspection unit.

5. The wafer storage container cleaning device according to claim 2, further comprising:
a disassembly/connection stage that disassembles and connects a wafer storage container main body and a door of the wafer storage container, wherein
the control unit
controls the robot so as to convey the wafer storage container to the disassembly/connection stage before cleaning by the cleaning unit, and controls the disassembly/connection stage so as to disassemble the wafer storage container into the wafer storage container main body and the door in the disassembly/connection stage,
controls the robot so as to convey the door to the disassembly/connection stage after cleaning by the cleaning unit, controls the robot so as to convey the wafer storage container main body to the disassembly/connection stage after inspection by the second inspection unit, and controls the disassembly/connection stage so as to connect the wafer storage container main body and the door in the disassembly/connection stage, and
controls the robot so as to temporarily place, on the disassembly/connection stage, the wafer storage container waiting to be unloaded to the first stocker or the second stocker.

6. The wafer storage container cleaning device according to claim 5, wherein a plurality of the disassembly/connection stages are provided.

7. A wafer storage container cleaning device comprising:
a casing that includes therein a cleaning unit that cleans at least a wafer storage container, and a robot that conveys the wafer storage container;
a load port that is provided across an inside and an outside of the casing;
a first inspection unit that is provided inside the casing in the load port and inspects a flange portion of the wafer storage container; and
a control unit that controls the robot, wherein
the control unit controls the robot so as to convey the wafer storage container inspected by the first inspection unit from the load port to the cleaning unit.

8. A wafer storage container cleaning method comprising:
a process of performing a first inspection for inspecting a state of a grip target portion of a wafer storage container;
a process of cleaning a storage space of the wafer storage container for which the first inspection has been completed; and
a process of performing a second inspection for inspecting a state of the storage space of the wafer storage container for which cleaning of the storage space has been completed, wherein
on a basis of an inspection result in the process of performing the first inspection, the process of cleaning the storage space is performed only on the wafer storage container for which it is determined that the wafer storage container is in a usable state.

9. The wafer storage container cleaning method according to claim 8, wherein in the process of performing the first inspection, in a case where it is determined that the wafer storage container is not in the usable state, the wafer storage container is conveyed to a position different from a position where the storage space of the wafer storage container is cleaned by a robot.
